(19) United States
(12) Patent Application Publication
(10) Pub. No.: US 2026/0015225 A1
(43) Pub. Date: Jan. 15, 2026

(54) METHOD FOR PRODUCING MICROELECTROMECHANICAL STRUCTURES

(71) Applicant: Robert Bosch GmbH, Stuttgart (DE)

(72) Inventors: Achim Harzheim, Tuebingen (DE); Arnd Kaelberer, Schlierbach (DE); Heiko Stahl, Reutlingen (DE); Jochen Tomaschko, Gaeufelden (DE); Hartmut Kueppers, Reutlingen (DE)

(21) Appl. No.: 18/994,241

(22) PCT Filed: Jul. 20, 2023
(86) PCT No.: PCT/EP2023/070097

§ 371 Date: Jan. 14, 2025

(30) Foreign Application Priority Data
Aug. 17, 2022 (DE) 10 2022 208 514.0

(51) Int. Cl. B81C 1/00

(52) U.S. Cl. CPC B81C 1/00492; B81C 2201/0104; B81C 2201/0109; B81C 2201/0132; B81C 2201/0133; B81C 2201/014; B81C 2201/016; B81C 2201/0177

(57) ABSTRACT

A method for producing microelectromechanical structures. The method includes: providing a carrier substrate having a central layer, and an insulation layer which is disposed on one side of the central layer and is applied to the surface; applying a silicon layer to the insulation layer; structuring the silicon layer forming trenches through the silicon layer in places; passivating the silicon layer, wherein the trenches are filled and a passivation layer forms; structuring the passivation layer, sacrificial regions and functional regions being formed, the sacrificial regions being free of the passivation layer in places; removing part of the carrier substrate forming a new surface; forming a second insulation layer on the new surface; repeating the applying, structuring and passivating for a second silicon layer on the second insulation layer and structuring for a second passivation layer to form sacrificial regions and functional regions and removing all of the sacrificial regions.

### FIELD

The present invention applies to the field of microelectromechanical devices and relates to a method for producing microelectromechanical structures. It also relates to a microelectromechanical device.

### BACKGROUND INFORMATION

Germany Patent Application No. DE 10 2006 032 195 A1 describes a method for producing MEMS structures. Germany Patent Application DE 10 2009 029 202 A1 describes a micromechanical system and a method for producing a micromechanical system. The so-called EPyC process (EPyC: epitaxial polysilicon cycle) for producing microelectromechanical structures having a large vertical extension, which uses epitaxial polysilicon as a functional and sacrificial material and builds a layer structure of epitaxial polysilicon layers using repeating cycles, is described in Germany Patent Application No. DE 10 2015 206 996 A1.

### SUMMARY

According to the present invention, a method for producing microelectromechanical structures and a device comprising such microelectromechanical structures are provided.

According to a first aspect of the present invention, a method for producing microelectromechanical structures, for example structures for a microelectromechanical device, for example a device comprising a MEMS (microelectromechanical system), is provided. According to an example embodiment of the present invention, the method comprises providing a first carrier substrate, for example including at least substantially of silicon, with one or more central layers. The one or the multiple central layers are preferably one or more monocrystalline silicon layers which preferably have a layer thickness of 0.1 μm to 10.0 μm. Such monocrystalline silicon layers also preferably have a doping which is preferably designed such that the specific resistance of the doped silicon is in the range of 1 mΩ·cm to 5 mΩ·cm at 20° C. It is also possible to use multiple layers comprising different materials as central layers. The one or more central layers can already be structured, i.e., comprise recesses and/or openings, for example, and/or can undergo structuring, for instance using an etching process. This makes it possible to achieve electrical connections and insulation between specific regions of these and the silicon layers to be applied. Structuring can be carried out prior to the implementation of the following steps, for instance, and/or after partial removal of the first carrier substrate and/or, if the material of the central layer to be structured is suitable, also by means of a later etching process, for example by later silicon sacrificial layer etching. It is in particular also possible that the first carrier substrate is provided directly with one or more central layers that are structured. A first insulation layer is then formed on a surface of the first carrier substrate, in which case the first insulation layer is disposed on a first side of the one or more central layers and the first insulation layer itself is not part of the first carrier substrate. Such an insulation layer serves to provide electrical and mechanical insulation between the substrate and the silicon layer of the following first EPyC cycle. The surface of the first carrier substrate is preferably realized by a surface of one of the one or more central layers.

According to an example embodiment of the present invention, the first insulation layer is preferably a silicon oxide and/or silicon nitride layer. The first insulation layer preferably serves as an etch stop layer for later silicon sacrificial layer etching. The use of such an etch stop layer eliminates the need for complex and highly variable time-dependent etching processes. In particular in order to produce electrical connections through the insulation layer, this insulation layer can already be structured and/or can undergo structuring prior to the implementation of the further steps.

According to an example embodiment of the present invention, a first silicon layer is applied to the first insulation layer; for example bonded, sputtered and/or preferably grown, in particular epitaxially grown. Epitaxial growth in particular takes place at temperatures that are typically >600° C., preferably >900° C. Structuring of the first insulation layer can take place prior to this growth of the first silicon layer and/or after the removal of the first carrier substrate, i.e., from the opposite side. The applied first silicon layer can comprise or be a monocrystalline, a polycrystalline and/or an epi-polycrystalline silicon layer, for instance. The term epi-polycrystalline silicon layers refers to polycrystalline silicon layers that have been grown epitaxially, i.e. under epitaxial growth conditions. Such epi-polycrystalline silicon layers typically have thicknesses of more than 5 μm, often also several 10 μm.

According to an example embodiment of the present invention, epitaxial growth on the first insulation layer, for example a silicon oxide layer, can include prior application of a polysilicone starting layer, for example via CVD polysilicon deposition (CVD: chemical vapor deposition), onto the insulation layer, because polysilicon (polycrystalline silicon) typically cannot be epitaxialized directly on the insulation layer. This also applies to the second insulation layer and the passivation layers discussed below. Regions that are not covered by an insulation layer or a passivation layer can be filled by CVD polysilicon deposition which creates electrical contact with a silicon layer to be grown later. The result of this is the formation of a wiring layer. However, direct epitaxialization without a polysilicon starting layer can also be made possible by selecting a process control in which crystallization nuclei form by themselves. In the context of the present invention, the term epitaxial growth refers to both possible variants; i.e., indirect epitaxial growth using a starting layer to be applied at least in part beforehand and direct epitaxial growth without a starting layer.

According to an example embodiment of the present invention, a first carrier substrate comprising a silicon layer applied to a first insulation layer and a desired central layer can also be provided directly in the form of a raw wafer, such as an SOI wafer (SOI: silicon-on-insulator). A layer thickness of the first silicon layer and also of further applied silicon layers can be 0.5 to 100 μm, preferably 20 to 60 μm, for example.

This first silicon layer is structured to form trenches in the first silicon layer, wherein the trenches extend at least in places through the first silicon layer. Such structuring can be carried out by means of reactive ion etching (RIE) and/or deep reactive ion etching (DRIE), for example, and/or, in particular in the case of relatively thin silicon layers, by means of a plasma etching process.

The first silicon layer is then passivated, wherein the trenches are filled and a first passivation layer forms on a side of the first silicon layer facing away from the first insulation layer. The trenches are filled here by forming the first passivation layer in the trenches. The passivation layer preferably covers substantially the entire surface of the first silicon layer including the trenches. Passivation techniques such as thermal oxidation and/or tetraethyl orthosilicate deposition (TEOS deposition), silicon carbide deposition (SiC deposition), silicon carbonitride deposition (SiCN deposition), silicon nitride deposition (SiₓN_{y} deposition) or silicon oxynitride deposition (SiON deposition) can be used for passivation. Regions of the silicon layer that are not to be etched are protected from etching attack by the passivation layer. The regions of the silicon layer with access for an etching medium used for etching (sacrificial regions) can be etched completely. The passivation layer thus serves as a lateral and vertical etch stop, and can therefore have a function identical to that of the insulation layer. The produced passivation layers can be made of different materials depending on the passivation technique used; for example silicon oxide and/or silicon nitride. For instance, an oxide etching process can preserve the parts of the passivation layers that consist of silicon nitride, which can then be used for electrical insulation during operation of the layer system produced by the process.

The first passivation layer formed in this way is structured, wherein this structuring results in the formation of first sacrificial regions and first functional regions in the first silicon layer and the first sacrificial regions on the side of the first silicon layer facing away from the first insulation layer are free of the first passivation layer at least in places.

This is followed by the removal of a part of the first carrier substrate. This is done in such a way that a new surface of the one or more first carrier substrate is formed on a second side of the one or more central layers, wherein none of the one or more central layers are removed. The carrier substrate can thus be removed down to the first exposed central layer, for example. At this point, it is particularly easy to structure this first exposed central layer, for example by means of a suitable etching process, for example to produce electrical connections. Lastly, a second insulation layer is formed on the thus created new surface. This can optionally be structured in the same way as the first insulation layer, in particular to enable electrical connections through the second insulation layer. To produce electrical connections, it can therefore be advantageous for the first and/or the second insulation layer to already be structured and/or for structuring of the first and/or second insulation layer to be carried out. Likewise, it can be advantageous for the one or more central layers to already be structured and/or to undergo structuring.

According to an example embodiment of the present invention, the above steps of epitaxially applying, structuring and passivating are then repeated; this time for a second silicon layer and a second insulation layer instead of the first silicon layer or the first insulation layer. Similarly, a second passivation layer formed in the passivation step is structured in the same way as the first passivation layer to form second sacrificial regions and second functional regions in the second silicon layer. All of the sacrificial regions are then removed; for example by means of an etching process (silicon sacrificial layer etching). Such silicon sacrificial layer etching can also be used to structure the one or more central layers depending on the material of this layer or these layers. This is particularly useful when using a single silicon sacrificial layer etching to create a cavity that consists of sacrificial regions on both sides of the one or more central layers and penetrates the one or more central layers. Such a procedure requires suitable structuring of the first and the second insulation layers.

A method is therefore provided according to the present invention for integrating one or more central layers into a microelectromechanical structure that is built using the EPyC process. The method according to the present invention makes it possible to integrate a well-defined layer, for example a highly doped monocrystalline silicon layer (Si layer) with an exact layer thickness into a complex MEMS. This central layer or the central layers can be specified by a raw material for the carrier substrate or applied to such a substrate. For further details regarding the EPyC process, please refer to Germany Patent Application No. DE 10 2015 206 996 A1, which is hereby incorporated in its entirety as part of the present application.

A particularly advantageous example embodiment of the method according to the present invention is provided by the fact that the steps of applying, for example epitaxial growth, structuring and passivating the first silicon layer as described above are all repeated. The structuring of the first passivation layer is also repeated as described above. Alternatively or additionally, the corresponding steps can be repeated for the second silicon layer and the second passivation layer as well. Such repetition can occur several times, for example twice, three times, five times or ten times. In the context of such a repetition, the application is always carried out on a structured passivation layer (namely the currently outermost layer) instead of an insulation layer. This results in the formation and structuring of further silicon layers and further passivation layers on the first and/or on the second side of the one or more central layers. Layer systems can therefore be formed on both sides of the one or more central layers. Forming and structuring the further silicon layers and the further passivation layers creates further sacrificial regions and further functional regions in the further silicon layers. Structuring the further passivation layers also makes it possible to achieve electrical connections and insulation between specific regions of the silicon layers. This embodiment of the method according to the present invention can be used to easily produce functional layer sequences on both sides of the central layers. The stacked layers can be precisely aligned with one another. Every silicon layer can be structured and configured independently of other silicon layers. Interlocking and/or overlapping functional regions, in particular with respect to a vertical extension, are in particular possible too. The method also makes it possible to freely design electrical connections and insulation and mechanical connections and insulation within the functional regions. As part of this procedure, regions that are free of a passivation layer can be filled prior to the application of the next silicon layer by means of CVD polysilicon deposition in order to form a wiring layer. Such CVD polysilicon deposition can also be used to produce a starting layer during the step of applying the next silicon layer.

According to an example embodiment of the present invention, preferably after the removal of all of the sacrificial regions, at least one of the passivation layers is removed as well, at least in places, which possibly also includes exposing trenches and/or one of the insulation layers, i.e. parts of the first and/or the second passivation layer and/or one or more of the possibly existing further passivation layers and/or the first and/or the second insulation layer, for example in order to produce a desired mobility of the produced structures. This is advantageous in particular when the functional regions are advantageously completely fixed relative to one another by the method according to the present invention. Recesses and/or openings can be created in one of the produced passivation layers and/or trenches can be exposed, for instance. The passivation layer can also be removed completely. This can include exposing the trenches. The passivation layer, for example an oxide passivation layer, or parts thereof, can be removed by gas-phase etching, plasma etching and/or wet etching. The passivation layer or parts thereof can thus be removed particularly easily.

According to an example embodiment of the present invention, preferably prior to the removal of the parts of the first carrier substrate and thus also prior to the formation of the second insulation layer, the first carrier substrate (including the thus far applied layers and produced microelectromechanical structures) is rotated, wherein the rotation preferably takes place about an axis which extends parallel to the surface with an angle between 175° and 185°, preferably between 179° and 181° and particularly preferably 180°. This ensures that the second insulation layer and the following layers can be formed particularly easily, because the similar orientation enables devices to be used in a similar manner on both sides of the one or more central layers to form layers. This greatly simplifies the manufacturing process of the microelectromechanical structures to be produced.

It is particularly advantageous if parts of the first carrier substrate are removed by chemical-mechanical polishing (CMP). Such a procedure makes it possible to remove the carrier substrate with a high degree of precision until a first of the central layers appears, for instance.

According to a particularly preferred embodiment of the present invention, a second carrier substrate, preferably consisting substantially of silicon, is applied to a surface of a most recently formed passivation layer prior to the removal of parts of the first carrier substrate. Thus, after a three-dimensional structure has been built on one side of the first carrier substrate, a second carrier substrate is applied, namely on the same side on which the silicon layer or (if repeated) silicon layers and the insulation layer or (if repeated) the insulation layers were formed in the previous steps. This can be advantageous to increase the stability of the wafer for the following working steps. Such application of a second carrier substrate can include bonding, for example soldering and/or sintering, of the second carrier substrate. The second carrier substrate is preferably applied prior to any rotation of the first carrier substrate with the thus far produced layers and structures and/or prior to the structuring of the most recently formed passivation layer. Such structuring of the most recently formed passivation layer can also take place after later removal of the second carrier substrate. The second carrier substrate can preferably be removed prior to the removal of all of the sacrificial regions (typically by means of silicon sacrificial layer etching). Removal of the second carrier substrate prior to the removal of all of the sacrificial regions is particularly advantageous because the structures formed by the method are mechanically very sensitive after the removal of the sacrificial regions. This severely restricts the choice of possible methods for removing the carrier substrate if the sacrificial regions are removed first. The second carrier substrate is preferably removed by means of chemical-mechanical polishing (CMP).

According to an example embodiment of the present invention, preferably at least one of the epitaxially grown silicon layers, for example the first silicon layer and/or the second silicon layer and/or one of the further silicon layers, comprises or is a monocrystalline, a polycrystalline and/or an epi-polycrystalline silicon layer. A layer thickness of at least one of the epitaxially grown silicon layers, for example the first silicon layer and/or the second silicon layer and/or one of the further silicon layers, can furthermore be 0.5 to 100 μm, for instance, preferably 20 to 60 μm. Thin silicon layers are suitable as resilient elements for vertical deflections, for example. Thick silicon layers, on the other hand, are advantageous for producing electrode combs or also for filling large volumes or for removing them as sacrificial regions.

According to an example embodiment of the present invention, the structuring to form the trenches is preferably carried out using a trench process such as reactive ion etching (RIE) and/or deep reactive ion etching (DRIE) and/or using a plasma etching process. A plasma etching process is useful in particular for thin layers (thicknesses of a few micrometers). For thicker layers, DRIE can be used, for example.

According to a preferred configuration of the method according to the present invention, the passivation layer is structured using a dry etching process and/or a wet etching process. The passivation layer can thus be easily removed again without having to resort to a specific etching process.

According to an example embodiment of the present invention, it is furthermore advantageous if chemical-mechanical polishing (CMP) and/or, at least in places, additional doping by implantation and/or coating of this silicon layer takes place after the application of one of the silicon layers. In particular topological irregularities and height differences that occur in the case of epitaxial growth of the silicon layer can thus easily be planarized. Additional doping by implantation or coating makes it easy to set a specific resistance in the silicon layer. The grown silicon layers can be undoped, p-doped or n-doped.

The sacrificial regions are preferably removed at least partly by plasmaless and/or plasma-assisted etching, i.e., by means of silicon sacrificial layer etching processes. This makes it particularly easy to remove the sacrificial regions. Such plasmaless etching can be carried out using chlorine trifluoride (ClF₃), chlorine fluoride (ClF), chlorine pentafluoride (ClF₅), bromine trifluoride (BrF₃), bromine pentafluoride (BrF₅), iodine pentafluoride (IF₅), iodine heptafluoride (IF₇), sulfur tetrafluoride (SF₄), xenon difluoride (XeF₂) or similar substances, for example. Plasma-assisted etching can be carried out using fluorine plasma, chlorine plasma, and/or bromine plasma, for instance. Etching can in particular also be based on a combination of plasmaless and plasma-assisted etching.

According to a second aspect of the present invention, a microelectromechanical device, for example comprising a MEMS such as a micromirror array, which preferably comprises microelectromechanical structures produced using a method according to the present invention, is provided. According to an example embodiment of the present invention, the microelectromechanical device has two alternating sequences of structured silicon layers and structured passivation layers and comprises a central layer, for example consisting substantially of monocrystalline silicon, which is disposed between the two alternating sequences of structured silicon layers and structured passivation layers and can be structured, i.e., can in particular comprise recesses and/or openings.

The method according to the present invention makes it possible to easily integrate a well-defined layer with free properties into a microelectromechanical structure which is referred to in the context of this application as a central layer. The selection of the material of this central layer can in particular be flexible; monocrystalline silicon can be chosen, for instance, which has a higher electrical and thermal conductivity than polysilicon. Even particularly thin central layers with an exact layer thickness and low deviation can be integrated, for example, which cannot be achieved using CMP. Instead, a central layer on a raw wafer can be used, which can be reliably qualified and controlled. Building alternating sequences of structured silicon layers and passivation layers on both sides of one or more central layers makes it possible to utilize the desired characteristics of the one central layer or the multiple central layers, but also avoid any problems with the topography of these central layers by precisely defining them. The process according to the present invention is moreover also suitable for CMOS and high temperatures and is therefore in particular suitable for the mass production of MEMS.

### BRIEF DESCRIPTION OF THE DRAWINGS

Embodiments of the present invention are explained in more detail with reference to the figures and the following description.

FIG. 1A to 1G show schematic cross-sectional views to explain a method according to the present invention for producing microelectromechanical structures.

FIG. 2 shows a schematic flow chart to explain a method according to an example embodiment of the present invention for producing microelectromechanical structures.

FIG. 3 shows a schematic illustration of an example of a microelectromechanical device according to the present invention.

### DETAILED DESCRIPTION OF EXAMPLE EMBODIMENTS

In the following description of the example embodiments of the present invention, identical or similar elements are denoted by identical reference signs, wherein a repeated description of these elements is omitted in individual cases. The figures show the subject matter of the present invention only schematically.

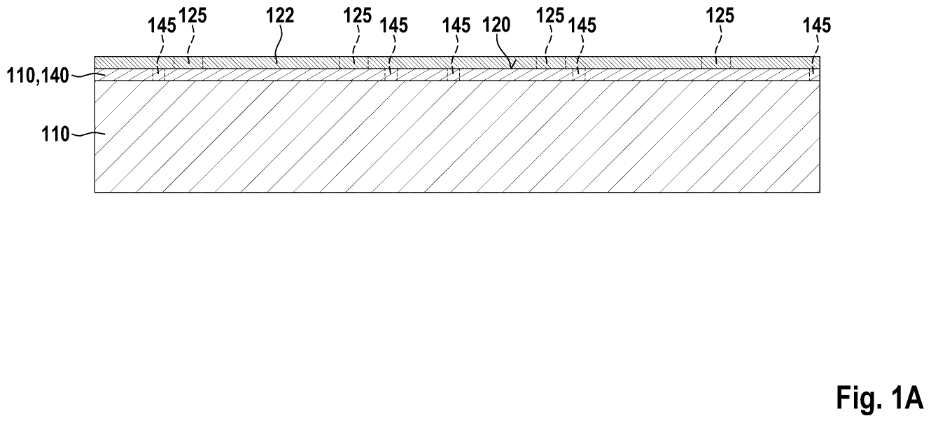

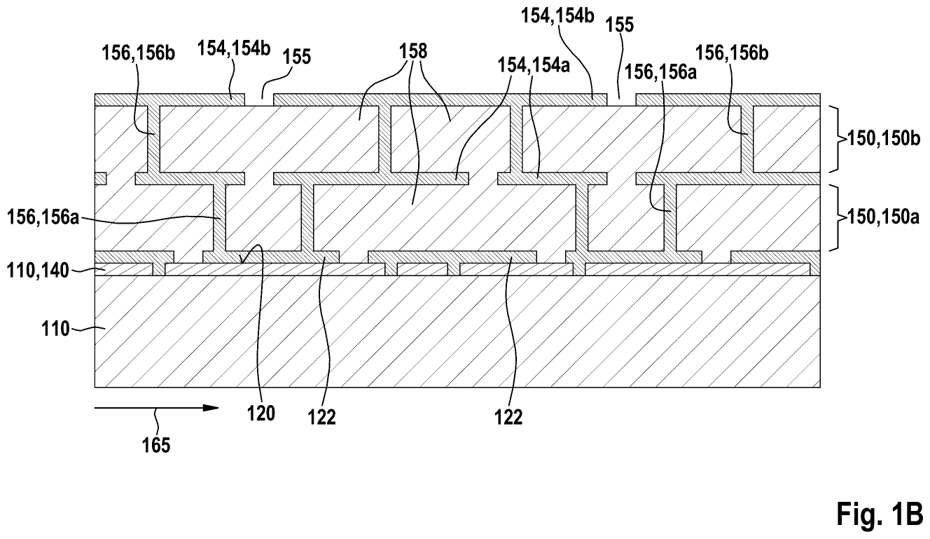

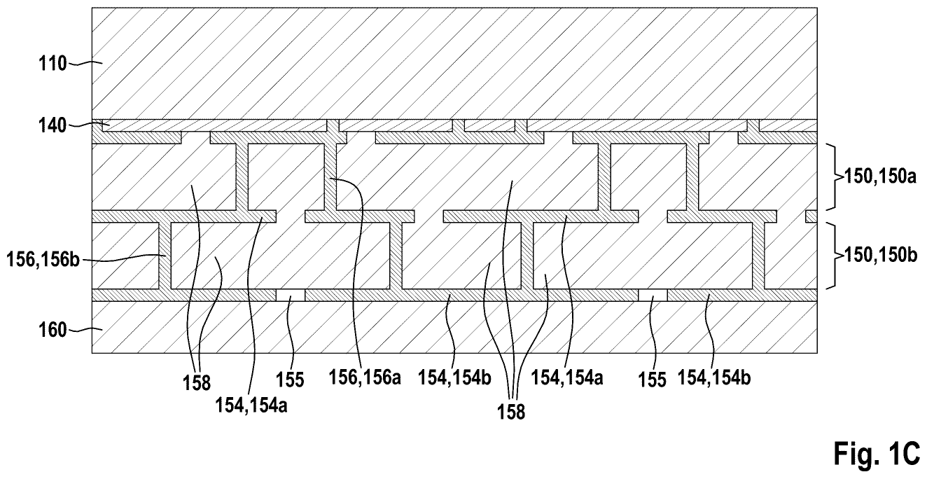

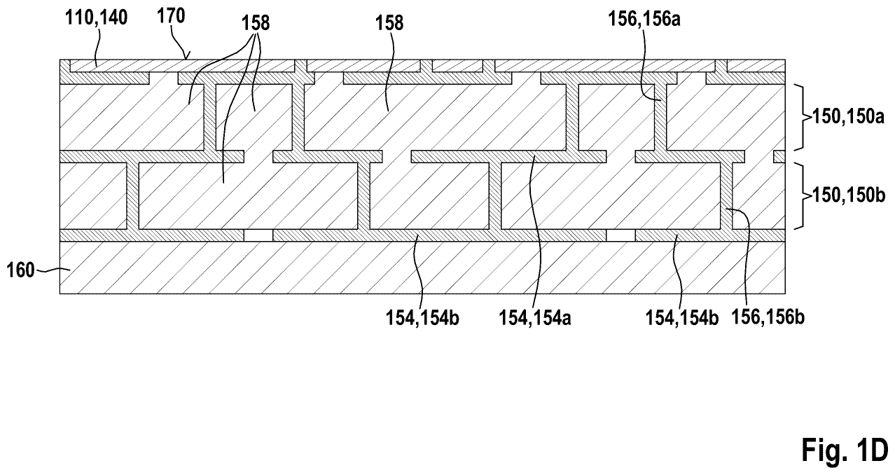

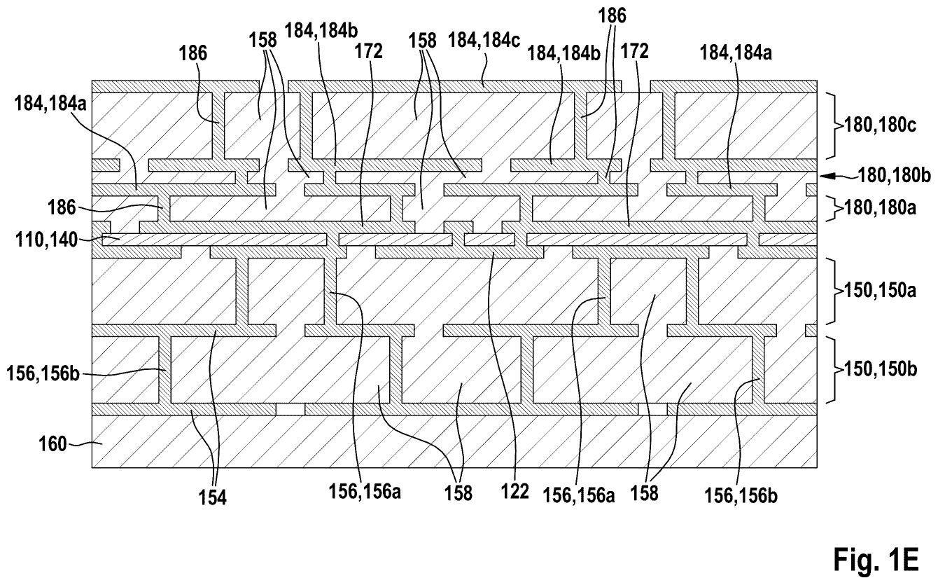

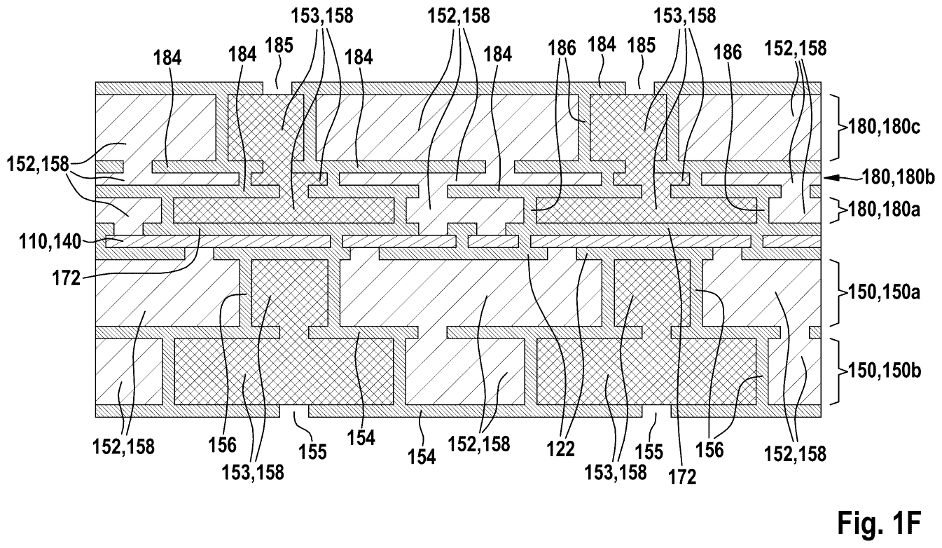

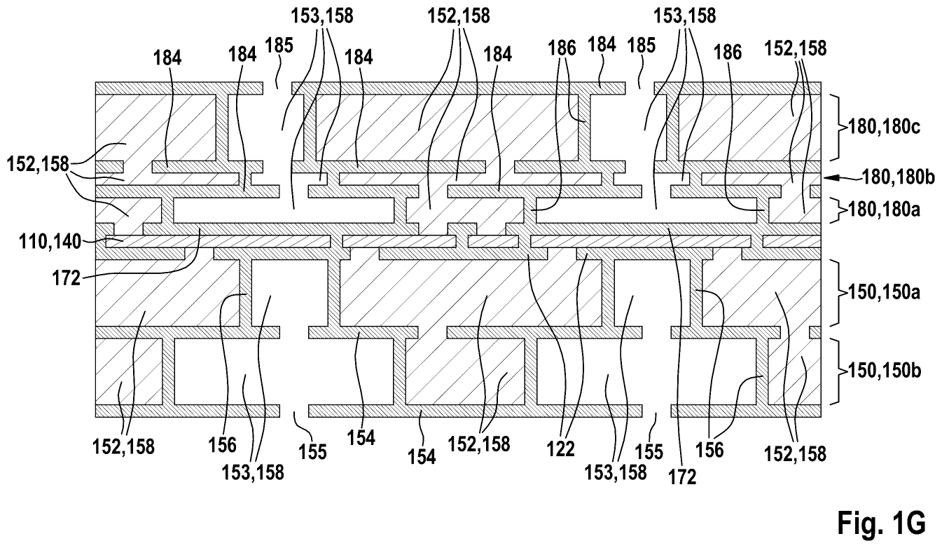

FIG. 1A to 1G show schematic cross-sectional views to explain an example of a method according to the present invention for producing microelectromechanical structures. For the sake of clarity, the insulation layers and the passivation layers (both inside and outside the drawn trenches) are shown in the same way in the figures. Also for the sake of clarity, the layers and the trenches as well as the functional and sacrificial regions are provided with reference signs purely as examples. Lastly, it should be noted that the figures show only a two-dimensional illustration. All of the layers shown in the figures as two-dimensional objects also have a third spatial dimension and can be structured along this dimension as well by the method according to the present invention, which enables an extremely high degree of flexibility.

FIG. 1A here shows a provided first carrier substrate 110 which comprises a central layer 140, for example a monocrystalline silicon layer. Also shown is a first insulation layer 122, for example made of silicon oxide, that has been applied to a surface 120 of the first carrier substrate 110 and is disposed directly on the central layer 140. The central layer 140 can be structured prior to the application of the first insulation layer 122 or the first carrier substrate 110 is provided directly with a structured central layer 140. The first insulation layer 122 can also be structured. This, for instance, makes it possible to later establish electrical connections between the layer systems on both sides of the central layer 140. The following FIGS. 1B to 1F assume a structured central layer 140 and a structured first insulation layer 122. In FIG. 1A, the recesses 145 of the central layer 140 and the recesses 125 of the first insulation layer 122 created during structuring are indicated by dashed lines.

A first silicon layer 150a is applied to the first insulation layer 122, for example epitaxially grown and then structured. This creates trenches 156a that extend through the first silicon layer 150a. Passivating the first silicon layer 150a fills the trenches 156a and at the same time forms a first passivation layer 154a on a side of the first silicon layer 150a facing away from the first insulation layer 122. This first passivation layer 154a, too, is structured, which creates sacrificial regions and functional regions 158 in the first silicon layer 150a. To show that sacrificial regions and functional regions 158 are materially identical, specifically formed by the silicon of the silicon layers, they are provided in this and the following figures with the same reference sign 158. Different reference signs are used in FIGS. 1F and 1G in order to be able to better illustrate the corresponding method steps and the differences between sacrificial regions and functional regions 158.

Structuring the layers ensures that the sacrificial regions can be removed later by an etching process. These steps of applying, structuring and passivating the first silicon layer 150a and structuring the first passivation layer 154a are then repeated one more time in the example shown in FIG. 1B. In this case, a further silicon layer 150b is applied to the first passivation layer 154a and this further silicon layer 150b is structured with further trenches 156b. These are filled by passivation. A further passivation layer 154b is created outside the further trenches 156b as well, which can likewise be structured at that point in time or also later (after removal of a second carrier substrate 160). In the shown example, recesses 155 are created here. The resulting structure is shown in FIG. 1B. Both silicon layers 150a, 150b are labeled here with a common reference sign 150; the common reference sign 156 identifies the filled trenches, the common reference sign 154 identifies the passivation layers outside the trenches 156.

A second carrier substrate 160 can now be applied to the exposed and most recently applied passivation layer 154b in order to mechanically stabilize the thus far produced microelectromechanical structures. Preferably after the application of the second carrier substrate 160, the first carrier substrate 110 including the thus far produced layers and structures can be rotated, wherein such a rotation preferably takes place about an axis 165 which extends parallel to the surface 120. The angle of the rotation can be 180°, for example. FIG. 1C illustrates the microelectromechanical structure of FIG. 1B after rotation of approximately 180° around the axis 165 which extends parallel to the surface 120 and application of a second carrier substrate 160, for example by means of bonding.

A part of the first (i.e. existing) carrier substrate 110 is now removed in such a way that the central layer 140 is not removed as well. The first carrier substrate 110 is instead removed exactly down to the central layer 140. This removal can be carried out by means of chemical-mechanical polishing, for example. As shown in FIG. 1D, a new surface 170 is defined by the central layer 140 which is now exposed on one side. Structuring of the central layer 140 can be present in the provided first carrier substrate 110 right from the beginning, for instance, or can take place at that point in time, i.e. after the removal of the first carrier substrate 110. The thus far created layers and structures are supported by the second carrier substrate 160. A second insulation layer 172 structured like the first insulation layer 122 now forms on the new surface 170, i.e. the exposed side of the central layer 140.

Silicon layers 180 can now be applied, structured and passivated once more, wherein the structuring of the passivation layers 184 results in the formation of sacrificial regions and functional regions 158. FIG. 1E shows three further silicon layers 180a, 180b, 180c formed and structured in this way with trenches 186 and three passivation layers 184a, 184b, 184c.

Lastly, as shown in FIG. 1F, the second carrier substrate 160 is removed, and the produced structures can now be exposed completely by removing all of the sacrificial regions 153, for example by means of plasmaless and/or plasma-assisted etching. The regions of the silicon layers 150 with access to an etching medium used in this etching process, for example via the recesses 155 and 185 of the outermost passivation layers 154 and 184, i.e. the sacrificial regions 153, are etched completely. These sacrificial regions 153 are identified in FIG. 1F by means of a different hatching. As an alternative to early creation of recesses 145 prior to application of the second carrier substrate 160 (see FIGS. 1B and 1C), said recesses can also be produced after the second carrier substrate 160 is removed.

After the removal of the sacrificial regions 153, the functional regions 152 remain as shown in FIG. 1G. Lastly, depending on the requirements, the passivation layers 154, 184 can be removed at least partly, including exposure of the trenches 156, 186 and/or the insulation layers 122, 172 (not shown in FIG. 1G), for example in order to produce a desired mobility of the produced microelectromechanical structures. Such a removal of the passivation layers 154, 184 can be carried out by gas-phase etching, plasma etching, or wet etching, for instance.

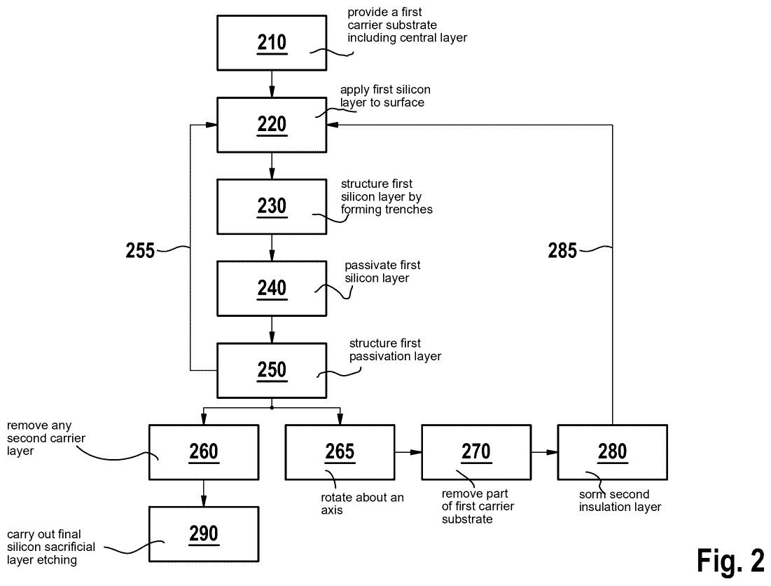

FIG. 2 shows a schematic flow chart to explain an example method according to the present invention for producing microelectromechanical structures. After providing 210 a first carrier substrate 110 comprising at least one central layer 140, a first silicon layer 150a is applied to a surface 120 of this first carrier substrate 110, for example epitaxially grown. This first silicon layer 150a is then structured 230 by forming trenches 156 that extend at least in places through the first silicon layer 150a. After passivating 240 the first silicon layer 150a, which is accompanied by filling the trenches 156, a first passivation layer 154a also forms outside the trenches 156. This is disposed on the side of the first silicon layer 150a facing away from the first insulation layer 122. The thus created first passivation layer 154a is now structured in step 250 to define sacrificial regions 153 and functional regions 152. These steps for forming structured applied silicon layers 150 can now be repeated as often as desired. This is symbolized by arrow 255.

As soon as all of the desired silicon layers 150 have been applied, the first carrier substrate 110 including the thus far produced layers is preferably rotated 265 about an axis 165 which extends parallel to the surface 120. Then, a part of the first carrier substrate 110 is removed (step 270), namely in such a way that none of the central layers 140 are removed. This results in the formation of a new surface 170. To mechanically support the thus far created structures, a second carrier substrate 160 can also be applied to the side of the central layers 140 to which the silicon layers 150 were applied in the previous steps. This second carrier substrate 160 is preferably applied prior to any rotation 265 and the removal 270 of the part of the first carrier substrate 110. A second insulation layer 172 is formed on the new surface 170 (step 280). Steps 220 to 250 are then repeated (arrow 285) to also form corresponding structures or silicon layers 180 on the second side of the central layers 140.

Here too, further silicon layers 180 can be applied, structured and passivated by repeating 255 steps 220 to 250 as often as desired and the resulting passivation layers 184 are structured as well. Once this has been done, any second carrier substrate 160 that may have been applied can be removed 260. Lastly, a final silicon sacrificial layer etching is carried out to remove 290 the newly created sacrificial regions 153 and thereby expose the produced structures. This can also be followed by another gas-phase etching, plasma etching and/or wet etching to at least partly remove the passivation layers 154. The microelectromechanical structures are thus completed; the method according to the present invention is concluded.

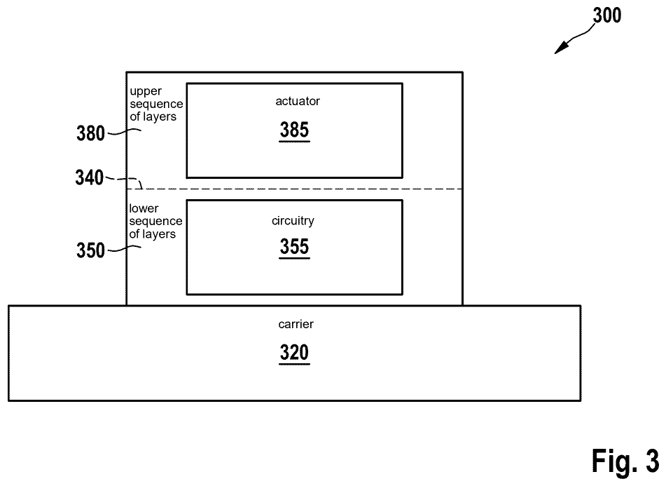

FIG. 3 shows a schematic illustration of an example of a microelectromechanical device 300 according to the present invention, for example comprising a MEMS. The microelectromechanical device 300 comprises microelectromechanical structures which have been produced by means of a method according to the present invention for producing microelectromechanical structures. These microelectromechanical structures are composed of two alternating sequences 350, 380 of structured silicon layers 150, 180 and structured passivation layers 154, 184 as well as a central layer 340, for example a monocrystalline silicon layer, disposed in between. The central layer 340 can be structured, i.e. in particular have recesses and/or openings. The lower alternating sequence 350 of structured silicon layers 150 and structured passivation layers 154, for example, makes it possible to realize a circuitry 355 of electrical connections that is configured to control an actuator 385, wherein the actuator 385 can in turn be realized with the upper alternating sequence 380 of structured silicon layers 180 and structured passivation layers 184. The lower sequence 350 of layers 150, 154 also makes it possible to realize micromechanical elements, however, just as parts of the upper sequence 380 of layers 180, 184 can be used for the circuitry 355. The microelectromechanical device 300 is disposed on a carrier 320, which can, for instance, include further electrical and electronic components that are used to control the microelectromechanical device 300.

The present invention is not limited to the embodiment examples described here and the aspects highlighted therein. Rather, within the range of the present invention, a large number of modifications are possible which lie within the abilities of a person skilled in the art.

1-13. (canceled)

14. A method for producing microelectromechanical structures, comprising the following steps:
a) providing a first carrier substrate having one or more central layers and a surface, wherein the first carrier substrate is provided with a first insulation layer which is disposed on a first side of the one or more central layers and is formed on the surface;
b) applying a first silicon layer to the first insulation layer;
c) structuring the first silicon layer to form trenches in the first silicon layer, wherein the trenches extend at least in places through the first silicon layer;
d) passivating the first silicon layer, wherein the trenches are filled and a first passivation layer forms on a side of the first silicon layer facing away from the first insulation layer;
e) structuring the first passivation layer, wherein first sacrificial regions and first functional regions form in the first silicon layer and the first sacrificial regions on the side of the first silicon layer facing away from the first insulation layer are free of the first passivation layer at least in places;
f) removing a part of the first carrier substrate in such a way that a new surface of the first carrier substrate is formed on a second side of the one or more central layers and none of the one or more central layers are removed;
g) forming a second insulation layer on the new surface;
h) repeating steps b to e for applying, structuring, and passivating a second silicon layer on the second insulation layer, structuring a second passivation layer to form second sacrificial regions and second functional regions in the second silicon layer; and
i) removing all of the first and second sacrificial regions.

15. The method according to claim 14, wherein steps b to e of applying, structuring and passivating the first silicon layer and structuring the first passivation layer and/or structuring and passivating the second silicon layer and structuring the second passivation layer are repeated, wherein the applying is carried out in each case on a structured passivation layer as a result of which further silicon layers and further passivation layers are formed and structured on the first and/or on the second side of the one or more central layers to create further sacrificial regions and further functional regions in the further silicon layers.

16. The method according to claim 14, wherein, after the removing all of the first and second sacrificial regions, at least one of the first and second passivation layers and/or one of the first and second insulation layers is removed at least in places.

17. The method according to claim 14, wherein the first carrier substrate is rotated prior to the removal of the part of the first carrier substrate, wherein the rotation takes place about an axis which extends parallel to the surface with an angle between 175° and 185°.

18. The method according to claim 14, wherein the part of the first carrier substrate is removed using chemical-mechanical polishing.

19. The method according to claim 14, wherein, prior to the removal of the part of the first carrier substrate, a second carrier substrate is applied to a surface of a most recently formed passivation layer, wherein the second carrier substrate is removed prior to the removal of all of the first and second sacrificial regions and/or using chemical-mechanical polishing.

20. The method according to claim 14, wherein at least one of the applied first and second silicon layers includes or is: (i) a monocrystalline silicon layer and/or (ii) polycrystalline silicon layer and/or (iii) an epi-polycrystalline silicon layer.

21. The method according to claim 14, wherein a layer thickness of at least one of the applied first and silicon layers is 0.5 to 100 μm.

22. The method according to claim 14, wherein the structuring for forming the trenches is carried out using a trench process and/or using a plasma etching process.

23. The method according to claim 14, wherein the first and second passivation layer is structured using a dry etching process and/or a wet etching process.

24. The method according to claim 14, wherein after the application of one of the first and second silicon layers, chemical-mechanical polishing and/or, at least in places, additional doping by implantation and/or coating of the one of the first and second silicon layer takes place.

25. The method according to claim 14, wherein the first and second sacrificial regions are removed at least in part by plasmaless and/or plasma-assisted etching.

26. A microelectromechanical device, comprising:
microelectromechanical structures including two alternating sequences of structured silicon layers and structured passivation layers; and
a central layer which is disposed between the two alternating sequences of structured silicon layers and structured passivation layers;
wherein the micromechanical structures are produced by performing the following steps:
a) providing a first carrier substrate having the central layer and a surface, wherein the first carrier substrate is provided with a first insulation layer which is disposed on a first side of the one or more central layers and is formed on the surface,
b) applying a first silicon layer to the first insulation layer,
c) structuring the first silicon layer to form trenches in the first silicon layer, wherein the trenches extend at least in places through the first silicon layer,
d) passivating the first silicon layer, wherein the trenches are filled and a first passivation layer forms on a side of the first silicon layer facing away from the first insulation layer,
e) structuring the first passivation layer, wherein first sacrificial regions and first functional regions form in the first silicon layer and the first sacrificial regions on the side of the first silicon layer facing away from the first insulation layer are free of the first passivation layer at least in places,
f) removing a part of the first carrier substrate in such a way that a new surface of the first carrier substrate is formed on a second side of the one or more central layers and none of the one or more central layers are removed,
g) forming a second insulation layer on the new surface,
h) repeating steps b to e for applying, structuring, and passivating a second silicon layer on the second insulation layer, structuring a second passivation layer to form second sacrificial regions and second functional regions in the second silicon layer, and
i) removing all of the first and second sacrificial regions.
